(19) United States
(12) Patent Application Publication
(10) Pub. No.: US 2007/0189909 A1
(43) Pub. Date: Aug. 16, 2007

(54) Apparatus for manufacturing semiconductor devices

(75) Inventor: Sung-Chul Youn, Hwaseong-si (KR)

Correspondence Address: MILLS & ONELLO LLP, ELEVEN BEACON STREET, SUITE 605, BOSTON, MA, 02108, US

(73) Assignee: Samsung Electronics, Co., Ltd.

(21) Appl. No.: 11/704,775

(22) Filed: Feb. 9, 2007

(30) Foreign Application Priority Data
Feb. 10, 2006 (KR) 10-2006-0013187

(51) Int. Cl. G11C 7/00

(52) U.S. Cl. 417/248; 365/205; 365/203; 60/791; 417/313

(57) ABSTRACT

Provided are apparatus and methods for manufacturing semiconductor devices and more specifically exhaust system apparatus and methods used in conjunction with a plurality of semiconductor processing chambers. The overall apparatus includes a plurality of process modules in which a semiconductor process is performed and an exhaust module to which the process modules are independently connected by fluid exhaust lines. The exhaust module amplifies an exhaust functionality of the system by more effectively and reliably drawing exhaust material from the process modules to be efficiently and effectively exhausted from the system.

### CROSS-REFERENCE TO RELATED APPLICATIONS

This U.S. non-provisional patent application claims priority under 35 U.S.C. §119 of Korean Patent Application No. 2006-13187, filed on Feb. 10, 2006, the entire contents of which are hereby incorporated by reference.

### BACKGROUND OF THE INVENTION

The present invention disclosed herein relates to an exhaust system apparatus used in connection with manufacturing semiconductor devices, and more particularly, to an exhaust system apparatus for manufacturing semiconductor devices which demonstrates improved functionality, reliability, and performance.

Generally, an apparatus for manufacturing semiconductor devices processes a wafer under a variety of environments and process conditions. That is, the apparatus for manufacturing semiconductor devices processes the wafer by repeating a variety of unit processes such as a photolithograph, diffusing, etching, chemical vapor deposition, physical vapor deposition, and other such fabrication processes. Each of the unit processes generally uses a variety of toxic gases and/or toxic solutions. Therefore, an exhaust system apparatus is designed to exhaust process byproducts and unreacted process reagents, such as fumes or residual gases, out of a semiconductor line.

FIG. 1 is a schematic illustration of a conventional exhaust system apparatus for manufacturing semiconductor devices. Referring to FIG. 1, a conventional exhaust system apparatus for manufacturing semiconductor devices typically includes a plurality of process modules 10, 20, 30, and 40 in which a variety of unit processes are actually performed. The process modules 10, 20, 30 and 40 are commonly connected to an exhaust line 53 of an exhaust module 50 through respective exhaust lines 15, 25, 35, and 45. An ejector 51 sucks exhaust materials introduced to and passed through the exhaust line 53 from the several process modules 10, 20, 30 and 40 using, for example, venturi effect. The amount of air introduced into the ejector 51 can be properly adjusted by a regulator.

Since the plural common modules 10, 20, 30 and 40 are commonly connected to the exhaust module 50, the exhaust ability of the exhaust module 50 sometimes is not uniform and may be unstable. Therefore, in order to insure effective exhausting of the exhaust material from a particular module, such as from a chamber 11 of module 10, an orifice block, for example orifice block 12, for properly controlling the exhaust pressure is provided as part of the process module 10. A damper 14 for adjusting a flow rate of the exhaust material and a pressure sensor 13 for detecting the pressure are also shown mounted on the orifice block 12. Likewise, the other process modules 20, 30, and 40 would typically have substantially the identical structure to the process module 10, as shown in FIG. 1.

As described above, even when a pressure differential is generated in the exhaust module 50, the orifice blocks 12, 22, 32, and 42 function to prevent the pressure differential from adversely affecting the exhaust pressures of the process modules 10, 20, 30, and 40. The pressure sensors 13, 23, 33, and 43, respectively, function to stop the operation of each process module which might be in trouble by detecting the exhaust pressures of the process modules 10, 20, 30, and 40. However, when any of the orifice blocks 12, 22, 32, and 42 becomes blocked by the exhaust material, it becomes essentially impossible to precisely control the exhaust pressure. When the orifice blocks 12, 22, 32, and 42 are blocked by the exhaust material, the pressure sensors 13, 23, 33, and 43 respectively lose their inherent function.

Because of structural considerations, a distance between the chambers 11, 21, 31, 41 and the ejector 51 increases due to the exhaust line 53 and the respective orifice blocks 12, 22, 32, 42. Furthermore, since a diameter of the respective exhaust lines 15, 25, 35, 45, and 53 is relatively small (e.g., ¼″ or ½″), the exhaust function of such an apparatus may not be effectively realized due to the relatively small diameter of each exhaust line and also due to the increased distance between the chambers 11, 21, 31, 41 and the ejector 51. Moreover, due to the relatively complicated structure of such an apparatus for exhausting the exhaust materials, the maintenance and repair costs increase as well as the time lost and resulting inconvenience.

These and other problems with and limitations of the prior art apparatus in this field are overcome in whole, or at least in part, by the exhaust system apparatus of this invention.

### SUMMARY OF THE INVENTION

Accordingly, the present invention provides an exhaust system apparatus for manufacturing semiconductor devices, which can effectively exhaust the exhaust materials from the manufacturing operations.

The present invention also provides an exhaust system apparatus for manufacturing semiconductor devices, which can reduce the maintenance and repair costs and also reduce lost time and inconvenience.

The present invention also provides an exhaust system apparatus for manufacturing semiconductor devices, which uses an air amplifying phenomenon using the Coanda effect.

Embodiments of the present invention provide exhaust system apparatuses for manufacturing semiconductor devices, such apparatuses generally including: a plurality of process modules in which a semiconductor process is performed; and an exhaust module to which each of the process modules is independently connected, wherein the exhaust module amplifies and effectively sucks exhaust materials from the process modules.

In some embodiments, the exhaust module may include a fluid amplifier for amplifying and sucking the exhaust material using the Coanda effect through an introduction of compressed fluid. The exhaust module may include a regulator, which may be combined with the fluid amplifier to control an amount of the compressed fluid that is introduced. The exhaust module may also include a pressure regulator, which may be combined with the fluid amplifier to control an exhaust pressure of the exhaust materials. The pressure regulator may further include a damper for controlling an amount of the exhaust materials being exhausted. The exhaust module may additionally include a pressure sensor for detecting an exhaust pressure of the exhaust materials.

In other embodiments, each of the process modules of an apparatus according to this invention includes a chamber providing an enclosed space in which one or more semiconductor fabrication steps are performed, an exhaust line providing a flow path for the exhaust materials generated from the chamber to the exhaust module, and a pressure sensor installed on the exhaust line to detect exhaust pressure of the exhaust line. The pressure sensor may be disposed to be closer to the exhaust module with which it is associated than to the chamber.

In other embodiments of the present invention, exhaust system apparatuses for manufacturing semiconductor devices include: a plurality of chambers in which semiconductor manufacturing processes are performed; a plurality of chamber exhaust lines each associated with one of the plurality of chambers; a fluid amplifier to which the chamber exhaust lines are commonly and/or individually fed whereby the exhaust materials are amplified and introduced from the exhaust lines by means of the Coanda effect; and a damper for adjusting an exhaust amount of the exhaust materials that are introduced into the fluid amplifier.

In some embodiments, the apparatuses according to this invention may further include a plurality of pressure sensors installed on the respective chamber exhaust lines to detect exhaust pressures of the respective chamber exhaust lines. These pressure sensors may be advantageously disposed to be closer to the fluid amplifier than to the respective chambers.

In other embodiments, the apparatuses according to this invention may further include a regulator for controlling an amount of the compressed fluid introduced into the fluid amplifier. These apparatuses may further include a pressure sensor for detecting exhaust pressure of the exhaust materials exhausted from the fluid amplifier.

In still other embodiments of the present invention, exhaust system apparatuses for manufacturing semiconductor devices include: a plurality of chambers in which semiconductor manufacturing processes are conducted and exhaust material(s) is (are) generated; a plurality of chamber exhaust lines each associated with one of the chambers to provide an exhaust path from each chamber for the exhaust materials; a fluid amplifier comprising a first fluid inlet to which the exhaust lines are commonly and/or individually combined and to which the exhaust material(s) is (are) introduced; a conduit extending from the first fluid inlet defining a front end of the conduit; a second fluid inlet through which compressed fluid is introduced and which is installed at a side end of the conduit; and a fluid outlet, which defines a rear end of the conduit and through which a mixed fluid of the exhaust material(s) and the compressed fluid is exhausted; a regulator, which is associated with the second inlet to control a flow rate of the compressed fluid; a pressure regulator including a damper, which is associated with the fluid amplifier to control an opening of the conduit to vary the flow rate of the mixed fluid; a pressure sensor for detecting the exhaust pressure of the conduit; and a main exhaust line extending from the pressure regulator to provide an exhaust path of the mixed fluid.

In some embodiments, the pressure sensors may advantageously be closer to the fluid amplifier than to the respective chambers. The fluid amplifier may use the Coanda effect through the introduction of the compressed fluid to amplify the exhaust effect and to assist with introducing the exhaust material(s). The compressed fluid used for this purpose may include pressurized air or nitrogen gas.

According to the present invention, since an exhaust system using the air-amplifying phenomenon as discussed uniformly maintains the exhaust pressure, the exhaust material(s) can be stably and effectively exhausted from the system. Furthermore, because the number of apparatus components can be reduced in accordance with this invention, the maintenance and repair costs can also be reduced.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified. In the figures:

FIG. 1 is a schematic illustration of a representative conventional exhaust system apparatus used in manufacturing semiconductor devices;

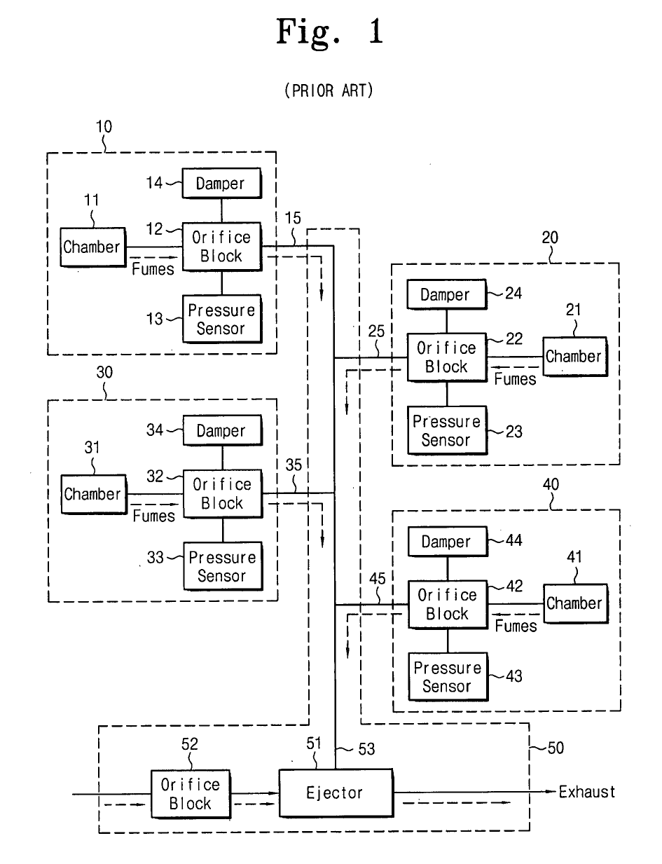

FIG. 2 is a schematic illustration of an exhaust system apparatus for manufacturing semiconductor devices according to an embodiment of the present invention;

FIG. 3 is an enlarged schematic sectional view of an exhaust module component of the apparatus of FIG. 2; and

FIG. 4 is an enlarged schematic sectional view of a fluid amplifier illustrating a Coanda effect in connection with the apparatus of FIG. 2 and the exhaust module of FIG. 3.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

Hereinafter, an exemplary embodiment of the present invention will be described in conjunction with the accompanying drawings.

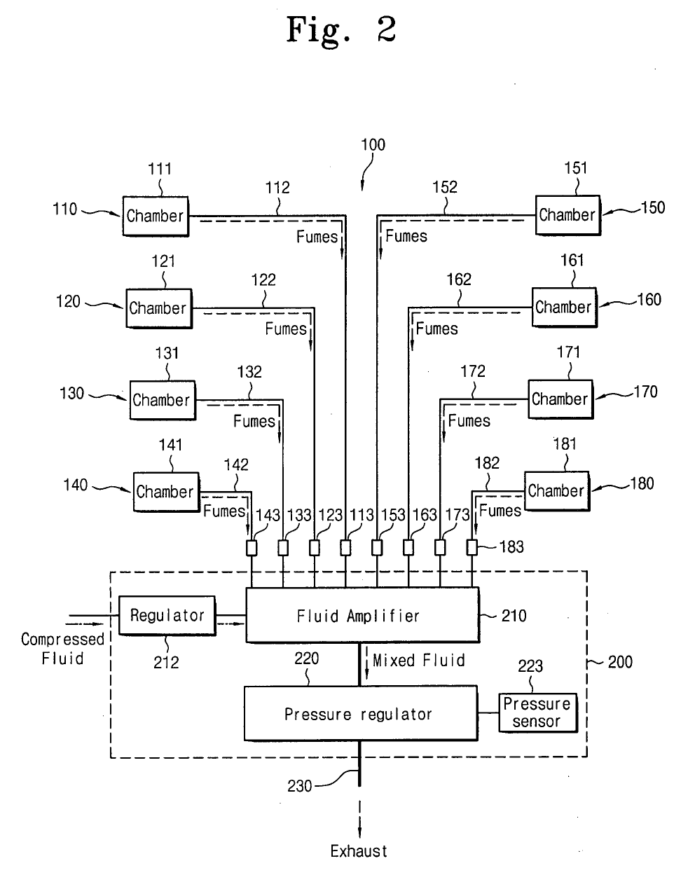

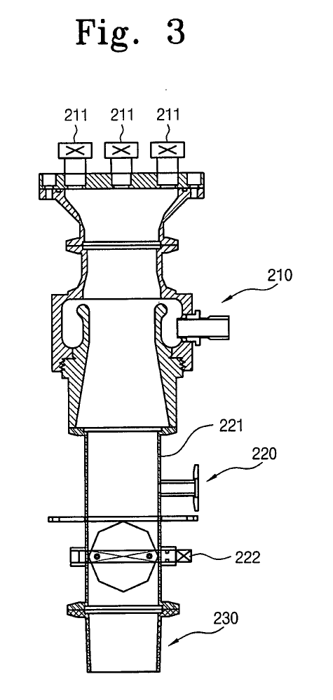

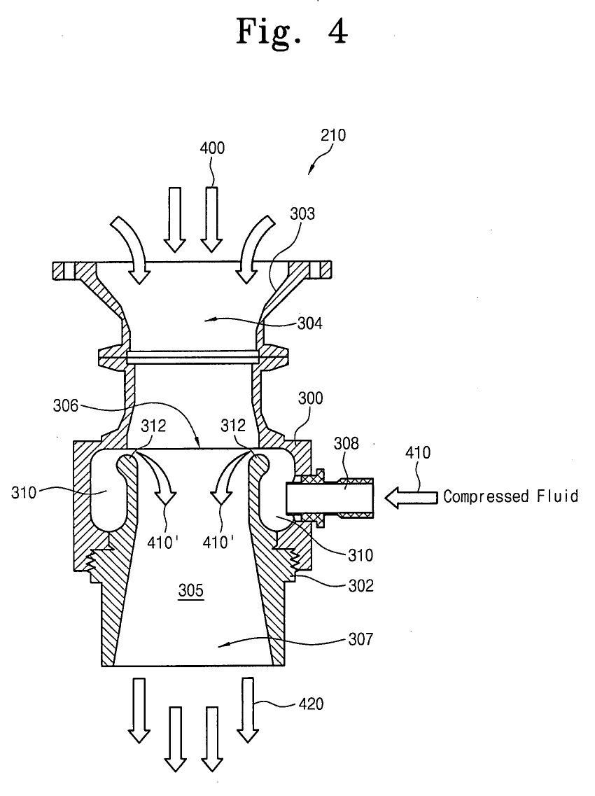

FIG. 2 is a schematic view of an exhaust system apparatus for manufacturing semiconductor devices according to an embodiment of the present invention; FIG. 3 is an enlarged schematic sectional view of an exhaust module component of the apparatus of FIG. 2; and FIG. 4 is an enlarged schematic sectional view of a fluid amplifier illustrating a Coanda effect in connection with the apparatus of FIG. 2 and the exhaust module of FIG. 3.

Referring to FIG. 2, an exhaust system apparatus 100 for manufacturing semiconductor devices includes a plurality of process modules 110, 120, 130, 140, 150, 160, 170, and 180, in each of which a variety of unit fabrication processes are performed, and a common exhaust module 200 for exhausting exhaust material(s), such as process byproducts or residual gases, which are exhausted from the process modules 110 through 180.

The process module 110 includes: a chamber 111 in which one or more semiconductor fabrication processes is (are) performed; a chamber exhaust line 112 for providing an exhaust path for the exhaust material(s); and a pressure sensor 113 for detecting the exhaust pressure of the exhaust line 112. The process modules 120 through 180 as shown in FIG. 2 also have substantially the identical structure to the process module 110 (with the components being correspondingly numbered). The exhaust module 200 includes a main exhaust module exhaust line 230 providing an external exhaust path for the exhaust material(s) and a fluid amplifier 210 for assisting with exhausting the exhaust material(s) from the chamber exhaust lines 112, 122, 132, 142, 152, 162, 172, and 182 to the main exhaust module exhaust line 230.

In the semiconductor device manufacturing exhaust system apparatus 100 of the present embodiment, the plural process modules 110 through 180 are shown as independently connected to the common exhaust module 200. The number of the process modules 110-180 is optional and may comprise a fewer or greater number of such process modules. The chamber exhaust lines 112 through 182 extending from the chambers 111 through 181 are shown as independently connected to the fluid amplifier 210. The exhaust materials being carried in the chamber exhaust lines 112 through 182 may tend to accumulate at bending portions of the chamber exhaust lines 112 through 182. Therefore, it is generally preferable that each chamber exhaust line 112 through 182 be designed to reduce or minimize bending portions as much as possible. That is, it is preferable that each exhaust line 112 through 182 be bent at no more than one portion, as shown in FIG. 2. It is further preferable that a distance between each chamber and the fluid amplifier be reduced as much as possible to maintain the lengths of the respective chamber exhaust lines as short as possible. That is, as the length of each chamber exhaust line is reduced, the exhaust performance or exhaust efficiency of the system is improved.

Pressure sensors 113 through 183 are provided along the respective chamber exhaust lines 112 through 182. As is well known, the pressure sensors transmit pressure information about the respective associated chamber exhaust lines 112 through 182 to a control unit (not shown) for controlling the operation of the semiconductor device manufacturing exhaust system apparatus 100. With pressure sensors 113 through 183, it becomes possible to individually monitor the exhaust pressures of the chamber exhaust lines 112 through 182. Therefore, when there is abnormal exhaust pressure in any chamber exhaust line, the semiconductor device manufacturing exhaust system apparatus 100 can be instantaneously controlled in response to the abnormality. The pressure sensors 113 through 183 may advantageously be disposed to be closer to the fluid amplifier 210 than to the respective associated chambers 111 through 181.

Referring to FIG. 3, the fluid amplifier 210 as illustrated is designed to use the Coanda effect to assist in moving and exhausting a large volume of ambient fluid using compressed fluid as a power source. When the compressed fluid is introduced into the fluid amplifier 210, a large volume of the exhaust material(s) is drawn from the exhaust lines 112 through 182 (FIG. 2) into the exhaust module 200, which is then exhausted out of the exhaust module 200 via exhaust line 230. Other components of the fluid amplifier as shown in FIG. 3 will be discussed hereinafter.

Referring to FIG. 4, the fluid amplifier 210 comprises two mating body portions 300 and 302. In the embodiment shown, internal threads on body portion 300 mate with external threads on body portion 302. The mated body portions 300 and 302 define an internal conduit 305 along which the fluid flows through the interior of the amplifier. The fluid amplifier 210 has a typical nozzle structure including an ambient fluid inlet region 304, a compressed fluid inlet 308, and a mixed fluid outlet 307.

The ambient fluid 400 introduced into the ambient fluid inlet 304 in part is flowed along an inclined surface portion inside body portion 300 and is channeled through a narrow passage region 306. The compressed fluid 410 is introduced into an annular chamber region 310 formed when body portions 300 and 302 are mated by means of the compressed fluid inlet 308. The compressed fluid 410 introduced into the annular chamber 310 passes through a narrow annular opening or passageway 312 into the internal conduit 305 where the now partially-expanded compressed fluid 410′ mixes with the ambient fluid 400 to form a mixed fluid 420. The mixed fluid 420 is exhausted out of the fluid amplifier 210 through the mixed fluid outlet 307.

When the compressed fluid 410 is introduced into the annular chamber 310 through the compressed fluid inlet 308, it flows quickly toward the mixed fluid outlet 307 through the narrow passage 312. At this point, the partially-expanded compressed fluid 410′ demonstrates a profile showing that at least a substantial portion of it flows along or adjacent to the internal body portion surface that defines the mixed fluid outlet 307 as a result of the Coanda effect and thereby enhances the exhausting process.

Referring again to FIG. 2, the exhaust module 200 further includes a compressed fluid regulator 212 for properly controlling an amount of compressed fluid (e.g., nitrogen or air) introduced into the fluid amplifier 210. Therefore, by using the regulator 212 to control the amount of the compressed fluid introduced into fluid amplifier 210, the exhaust pressure of the exhaust module 200 can be properly controlled. Furthermore, a pressure regulator 220 may be provided at a rear or outlet end of the fluid amplifier 210 to further assist in properly adjusting the exhaust pressure.

Referring again to FIG. 3, the pressure regulator 220 may include a damper 222 for properly adjusting the size of an opening through conduit 221, which is connected to an outlet end of the fluid amplifier 210. By the synchronized operation of the compressed fluid regulator 212 and the damper 222, the exhaust pressure of the main exhaust line 230 and/or the exhaust pressures of the chamber exhaust lines 112 through 182 can be properly adjusted. A pressure sensor 223 may be provided in the conduit 221 (FIG. 3) to detect the exhaust pressure of the conduit 221 and thus assist in properly adjusting the size of the fluid opening in conduit 221 at damper 222.

As described above, the chamber exhaust lines 112 through 182 are individually connected to the front or inlet end of the fluid amplifier 210. A plurality of ports 211 may be provided to connect to the respective exhaust lines 112 through 182 at the front (inlet) end of the fluid amplifier 210. The number of the ports 211 should ordinarily be equal to or greater than the number of chamber exhaust lines 112 through 182. For convenience, only three ports 211 are shown in FIG. 3, but it will be understood that eight of such ports 211 would be needed to accommodate the eight chamber exhaust lines 112 through 182 shown in FIG. 2. If, for example, the chamber exhaust lines 112 through 182 and the fluid amplifier are cylindrical, each chamber exhaust line might be designed to have an effective diameter of ⅜″ and the front (inlet) end of the fluid amplifier 210 would be designed to have an inner diameter of 100-110 mm.

The following will describe a representative operation of the above-described semiconductor device manufacturing exhaust system apparatus 100.

One or more semiconductor processes is (are) performed in the process modules 110 through 180. For example, a dielectric low oxygen concentration bake (DLB) process might be performed in one or more of the process modules 110 through 180. The DLB process is performed to enhance the condensation of a coating layer, which is uniformly formed by depositing a field oxide (Fox) chemical on a rotating wafer, using a high processing temperature. If the Fox fumes generated during the high temperature baking in the DLB process are not effectively exhausted but rather are allowed to accumulate, the accumulated fumes may back up into the chambers 111 through 181 and adversely impact this manufacturing step. For example, if the fumes back up into the chambers 111 through 181, the fumes can react with the wafers being fabricated, and this can cause a defect in or impairment of the wafer. Therefore, there is a need to improve the exhaust function to maintain proper exhaust pressure and thereby to prevent the fumes from accumulating and backing up into the chambers 111 through 181.

This need is realized by the structure of the exhaust system module 200 of the present invention, which can be operated as follows: compressed fluid is first introduced into the fluid amplifier 210; at this point, an amount of the compressed fluid is properly adjusted using the compressed fluid regulator 212; due to the introduction of the compressed fluid into the fluid amplifier 210 and the internal configuration of the fluid amplifier 210, the Coanda effect occurs inside the fluid amplifier 210 resulting in a significantly enhanced exhausting functionality. Therefore, the exhaust materials exhausted through the chamber exhaust lines 112 through 182 are effectively drawn into the fluid amplifier 210 and kept away from the chambers 111 through 181. The exhaust material(s) drawn into the fluid amplifier 210 is (are) then exhausted through the main exhaust line 230 (so-called factory exhaust). The flow rate of the exhaust material(s) being exhausted can be properly adjusted using the compressed fluid regulator 212 and/or the pressure regulator 220. The exhaust pressure of the main exhaust line 230 is detected and monitored by thepressure sensor 223. The exhaust pressures of the individual chamber exhaust lines 112 through 182 are detected and monitored by the respective pressure sensors 113 through 183. As described above, when the fluid amplifier 210 is used in accordance with this invention, a stable, reliable, and effective exhaust material flow can be maintained, and periodic lack of adequate exhaust pressure can thereby be avoided. Therefore, the periodic back-up of exhaust fumes, which is caused by the lack of stability in the exhaust pressure, can be prevented.

According to the present invention, since the exhaust system using the air amplifying phenomenon described herein uniformly maintains the system exhaust pressure, the exhaust material(s) can be reliably and effectively exhausted. Furthermore, since the number of operating components can be reduced relative to the conventional exhaust system used for this purpose, the maintenance and repair costs can be reduced. Therefore, process errors can be prevented, the yield can be improved, and the apparatus can be efficiently operated.

The above invention description is to be considered illustrative, and not restrictive, and the appended claims are intended to cover all modifications, enhancements, and other embodiments, which fall within the true spirit and scope of the present invention. Thus, to the maximum extent allowed by law, the scope of the present invention is to be determined by the broadest permissible interpretation of the following claims and their equivalents, and should not be construed as restricted or limited by the foregoing detailed description.

Having described the invention, what is claimed is:

1. An apparatus for manufacturing semiconductor devices, comprising:
a plurality of process modules in which one or more semiconductor processes are performed; and
an exhaust module to which the process modules are independently connected by fluid lines, wherein the exhaust module amplifies the exhaust functionality in drawing exhaust materials from the process modules through the fluid lines.

2. The apparatus of claim 1, wherein the exhaust module includes a fluid amplifier configured for introducing compressed fluid to an interior region so as to provide a Coanda effect for amplifying the exhaust functionality of the apparatus.

3. The apparatus of claim 2, wherein the exhaust module includes a regulator, which is associated with the fluid amplifier to control an introduction amount of the compressed fluid that is introduced.

4. The apparatus of claim 2, wherein the exhaust module includes a pressure regulator, which is associated with the fluid amplifier, to control exhaust pressure of the exhaust materials.

5. The apparatus of claim 4, wherein the pressure regulator includes a damper in an exhaust conduit receiving exhaust products from the fluid amplifier for controlling an exhaust amount of the exhaust materials.

6. The apparatus of claim 4, wherein the exhaust module includes an exhaust module pressure sensor for detecting exhaust pressure of the exhaust materials coming from the fluid amplifier.

7. The apparatus of claim 1, wherein each of the process modules comprises:
a chamber providing an enclosed space in which a semiconductor process is performed;
a chamber exhaust line providing at least a portion of a flow path of the exhaust materials generated from the chamber to the exhaust module; and
a pressure sensor installed on the chamber exhaust line to detect exhaust pressure of the chamber exhaust line.

8. The apparatus of claim 7, wherein the pressure sensor is disposed to be closer to the exhaust module than it is to the chamber.

9. An apparatus for manufacturing semiconductor devices, comprising:
a plurality of chambers in which one or more semiconductor processes are performed;
a chamber exhaust line associated with each of the chambers;
a fluid amplifier to which the chamber exhaust lines are connected wherein the draw of exhaust materials is amplified by the introduction of a compressed fluid; and
a damper for adjusting an exhaust amount of the exhaust materials coming from the fluid amplifier.

10. The apparatus of claim 9, further comprising a plurality of pressure sensors installed on the respective chamber exhaust lines to detect exhaust pressures of the respective chamber exhaust lines.

11. The apparatus of claim 10, wherein the pressure sensors are disposed to be closer to the fluid amplifier than to the respective chambers.

12. The apparatus of claim 9, wherein the fluid amplifier comprises an inlet through which a compressed fluid can pass into an interior region of the fluid amplifier and mix with exhaust materials to form a mixed stream, and an outlet for exhausting the mixed stream.

13. The apparatus of claim 12, further comprising a regulator for controlling an amount of the compressed fluid introduced into the fluid amplifier.

14. The apparatus of claim 9, further comprising an exhaust module pressure sensor for detecting exhaust pressure of the exhaust material exhausted from the fluid amplifier.

15. An apparatus for manufacturing semiconductor devices, comprising:
a plurality of chambers in each of which at least a semiconductor process is conducted and an exhaust material is generated;
a chamber exhaust line associated with each of the chambers to provide an exhaust path for the exhaust material;
a fluid amplifier comprising a first fluid inlet to which the chamber exhaust lines are connected and to which the exhaust material is introduced, an amplifier conduit extending from the first fluid inlet into an interior region of the fluid amplifier, a second fluid inlet through which compressed fluid is introduced into said interior region from a side of the amplifier conduit, and an amplifier outlet at an exhaust end of the amplifier conduit through which a mixed fluid of the exhaust material and the compressed fluid is exhausted;
a regulator which is associated with the second inlet to control a flow rate of the compressed fluid;
a pressure regulator including a damper, associated with the amplifier outlet to control an opening of the amplifier conduit to vary the flow rate of the mixed fluid out of the interior region, and a pressure sensor for detecting the exhaust pressure of the amplifier conduit at the amplifier outlet; and
a main exhaust line extending from the pressure regulator to provide an exhaust path of the mixed fluid.

16. The apparatus of claim 15, further comprising pressure sensors in the chamber exhaust lines, wherein the pressure sensors are positioned closer to the fluid amplifier than to the chambers.

17. The apparatus of claim 15, wherein the interior of the fluid amplifier is configured to produce a Coanda effect by the introduction of the compressed fluid to amplify and draw in the exhaust material.

18. The apparatus of claim 17, wherein the compressed fluid includes compressed air or pressurized nitrogen.

19. A method for enhancing the exhaust functionality of a semiconductor device manufacturing exhaust system apparatus, said method comprising the steps of: providing a fluid amplifier with an interior configured to produce a Coanda effect upon the introduction of a compressed fluid; connecting a plurality of semiconductor processing chambers by fluid lines to a first inlet of the fluid amplifier; introducing compressed fluid through a second inlet of the fluid amplifier; and exhausting a mixed stream of compressed fluid and exhaust from the processing chambers through an outlet of the fluid amplifier.

20. A method according to claim 19 further comprising one or more of the steps of: monitoring the pressure of exhaust materials in the fluid lines; regulating the flow of compressed fluid to the fluid amplifier; monitoring the pressure of the mixed stream being exhausted from the fluid amplifier; and, using a damper element positioned in the outlet of the fluid amplifier to regulate the pressure of mixed stream.
